(19) United States
(12) Patent Application Publication
(10) Pub. No.: US 2015/0349764 A1
(43) Pub. Date: Dec. 3, 2015

(54) Flip-Flop Having Integrated Selectable Hold Delay

(71) Applicant: Avago Technologies General IP (Singapore) Pte. Ltd., Singapore (SG)

(72) Inventors: Chun-Kiat Chua, Palm Residence (SG); Brian C. Miller, Fort Collins, CO (US)

(73) Assignee: Avago Technologies General IP (Singapore) Pte. Ltd., Singapore (SG)

(21) Appl. No.: 14/291,936

(22) Filed: May 30, 2014

(51) Int. Cl. H03K 5/14; H03K 3/037

(52) U.S. Cl. CPC H03K 5/14; H03K 3/037

(57) ABSTRACT

A circuit includes a flip-flop and a delay circuit integrated with the flip-flop, the delay circuit including at least one delay element, the flip-flop and delay circuit having a predefined architecture such that a delay provided by the delay circuit may have a selectable value while the flip-flop remains within the predefined architecture.

### BACKGROUND

An integrated circuit generally includes a number of different circuit elements and components that are selected and placed in the integrated circuit based on the functionality desired. A flip-flop is one type of circuit element that is used in many different integrated circuit applications to receive a value, store the value for a period of time, and then transition state to another value. A customized flip-flop instance typically includes one or more delay elements configured to delay the signal either before or after traversing the flip-flop. The delay can be implemented in a number of different ways. One way to implement the delay is to incorporate one or more signal buffers along with the flip-flop. Ordinarily, a flip-flop and the desired number of buffers are selected from a library and implemented in the circuit design when developing the integrated circuit. Unfortunately, implementing different delays typically requires implementing different configurations of flip-flops and buffers having different circuit layout details and different external connections, which leads to difficulties with circuit placement and signal routing.

Therefore, it would be desirable to have a way of implementing a flip-flop with a selectable delay without requiring circuit placement and routing changes for the different delays.

### SUMMARY

In an embodiment, a circuit comprises a flip-flop and a delay circuit integrated with the flip-flop, the delay circuit comprising at least one delay element, the flip-flop and delay circuit having a predefined architecture such that a delay provided by the delay circuit may have a selectable value while the flip-flop remains within the predefined architecture.

Other embodiments are also provided. Other systems, methods, features, and advantages of the invention will be or will become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1A is a schematic view illustrating an example of a conventional flip-flop.

FIG. 1B is a basic timing diagram of the flip-flop of FIG. 1A.

FIG. 2A is a schematic diagram illustrating an exemplary embodiment of a flip-flop having an integrated selectable hold delay.

FIG. 2B is a basic timing diagram of the flip-flop of FIG. 2A.

FIG. 3A is a schematic diagram illustrating another exemplary embodiment of a flip-flop having an integrated selectable hold delay.

FIG. 3B is a basic timing diagram of the flip-flop of FIG. 3A.

FIG. 4A is a schematic diagram illustrating another exemplary embodiment of a flip-flop having an integrated selectable hold delay.

FIG. 4B is a basic timing diagram of the flip-flop of FIG. 4A.

FIG. 5 is a schematic diagram illustrating a latch circuit having an exemplary embodiment of a flip-flop having an integrated selectable hold delay.

FIG. 6 is a diagram illustrating an embodiment of a layout of the flip-flop having an integrated selectable hold delay of FIG. 2A.

FIG. 7 is a diagram illustrating an embodiment of a layout of the flip-flop having an integrated selectable hold delay of FIG. 3A.

FIG. 8 is a diagram illustrating an embodiment of a layout of the flip-flop having an integrated selectable hold delay of FIG. 4A.

FIG. 9 is a block diagram showing the flip-flop having an integrated selectable hold delay of FIG. 2A placed in an integrated circuit.

FIG. 10 is a block diagram showing the flip-flop having an integrated selectable hold delay of FIG. 3A placed in the integrated circuit of FIG. 9.

FIG. 11 is a flow chart describing an exemplary method for using a flip-flop having an integrated selectable hold delay.

### DETAILED DESCRIPTION

In an exemplary embodiment, the flip-flop having an integrated selectable hold delay can be implemented in any integrated circuit where it is desirable to have a flip-flop with a variable and selectable hold delay and in which it is desirable to maintain the same footprint from flip-flop to flip-flop, regardless of the hold delay.

As used herein, the terms “floorplan” and “footprint” refer to a circuit layout in which the flip-flop is to be implemented.

As used herein, the term “integrated selectable hold delay” refers to a configurable delay circuit that can be implemented inside of a flip-flop to provide a range of delay values to a signal propagating through the flip-flop.

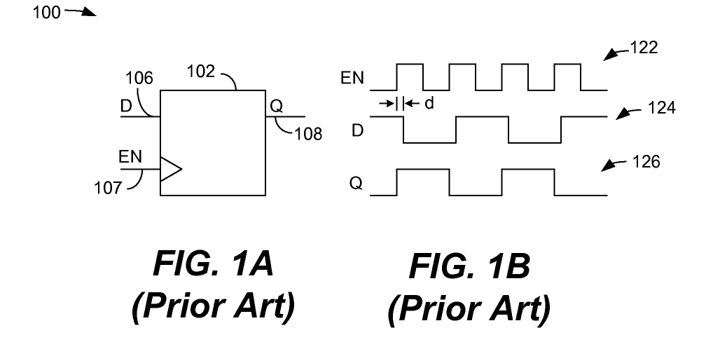

FIG. 1A is a schematic view illustrating an example of a conventional flip-flop. The flop-flop 102 comprises a data “D” input 106, and enable “EN” input 107, and a “Q” output 108. There may also be a “Q bar” output, which has the opposite polarity of the “Q” output. The “Q bar” output is not shown.

FIG. 1B is a basic timing diagram of the flip-flop of FIG. 1A. The EN signal is shown on trace 122, the D input is shown as trace 124 and the Q output is shown as trace 126. In this example, at the rising edge of the EN signal, the D input is provided through the flip-flop 102 causing the Q output to transition state from logic low to logic high. The flip-flop 102 may also be configured to transition state on the falling edge of the EN signal 122.

To ensure that the correct data is captured by the flip-flop, the D input signal should remain stable around the rising edge of the EN signal. The minimum time the D input should remain stable before the rising edge of the EN signal is known as the “setup time,” while the minimum time the D input should remain stable after the rising edge of the EN signal is known as the “hold time”. A typical hold time is depicted by the hold delay “d” in FIG. 1B. If the hold delay “d” is not managed correctly, it is possible that a wrong state may appear at the “Q” output at the rising edge of the “EN” signal. This condition is referred to as a “hold error” or “hold violation”, which is what is sought to be mitigated to avoid timing errors.

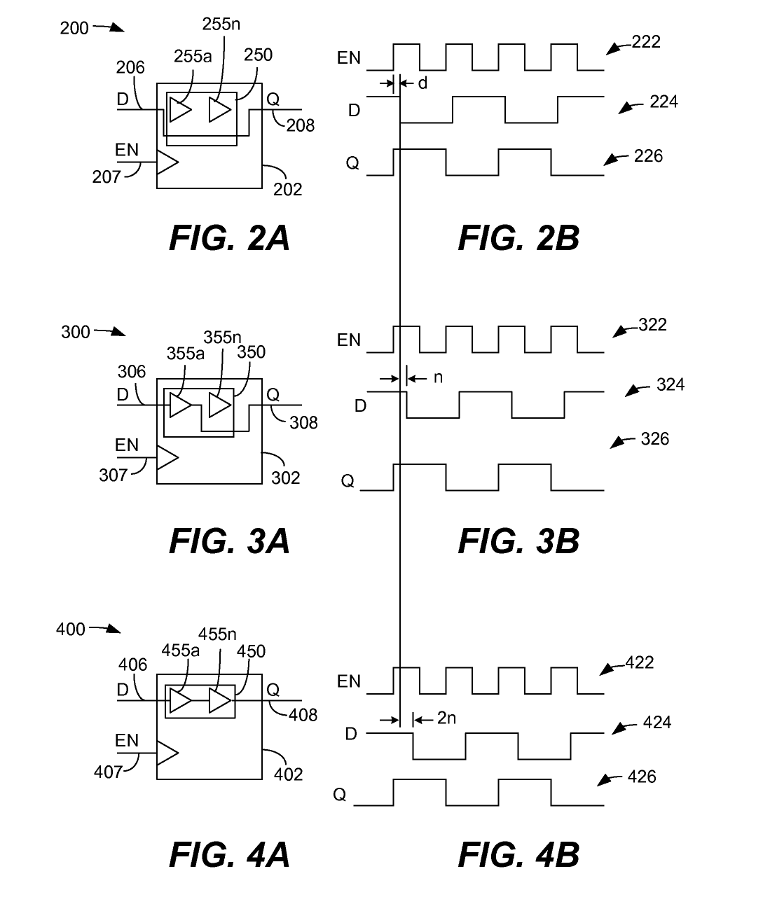

FIG. 2A is a schematic diagram 200 illustrating an exemplary embodiment of a flip-flop having an integrated selectable hold delay. The flop-flop 202 comprises a data “D” input 206, and enable “EN” input 207, and a “Q” output 208. There may also be a “Q bar” output, which has the opposite polarity of the “Q” output. The “Q bar” output is not shown.

The flip-flop 202 also comprises a variable delay element 250. The variable delay element 250 is schematically illustrated as having a delay element 255a and a delay element 255n. The variable delay element 250 may comprise more than two delay elements 255. In FIG. 2A, the D input on connection 206 is illustrated as bypassing the delay elements 255 and being coupled directly to the Q output on connection 208. Illustrative exemplary embodiments of the flip-flop 202 having the variable delay element 250 can comprise identical external connections, regardless of the delay provided by the variable delay element 250.

FIG. 2B is a basic timing diagram of the flip-flop of FIG. 2A. The EN signal is shown on trace 222, the D input is shown as trace 224 and the Q output is shown as trace 226. In this example, at the rising edge of the EN signal, the D input is provided through the flip-flop 202 causing the Q output to transition state from logic low to logic high. The flip-flop 202 may also be configured to transition state on the falling edge of the EN signal 222. There is a slight hold delay “d” from the time the EN signal transitions to the time the D signal transitions. In the embodiment shown in FIGS. 2A and 2B, there is no additional delay applied to the D input on connection 206 by the variable delay element 250.

FIG. 3A is a schematic diagram 300 illustrating an exemplary embodiment of a flip-flop having an integrated selectable hold delay. The flop-flop 302 comprises a data “D” input 306, an enable “EN” input 307, and a “Q” output 308. There may also be a “Q bar” output, which has the opposite polarity of the “Q” output. The “Q bar” output is not shown.

The flip-flop 302 also comprises a variable delay element 350. The variable delay element 350 is an alternative embodiment of the variable delay element 250 of FIG. 2A, and in this embodiment is schematically illustrated as having a delay element 355a and a delay element 355n. The variable delay element 350 may comprise more than two delay elements 355. In FIG. 3A, the D input on connection 306 is illustrated as being coupled to the delay element 355a and then to the Q output on connection 308 so that the D input signal on connection 306 experiences one delay period, that is, the delay provided only by the delay element 355a. Although the embodiment shown in FIG. 3A applies a delay period to the D input that is larger than a delay period applied to the D input signal by the flip-flop 202 in FIG. 2A, the variable delay element 350 and the flip-flop 302 has the same area, circuit layout and space requirements as the flip-flop 202 in FIG. 2A. Accordingly, the illustrative exemplary embodiment of the flip-flop 302 having the variable delay element 350 can comprise identical external connection as the flip-flop 202 having the variable delay element 250.

FIG. 3B is a basic timing diagram of the flip-flop of FIG. 3A. The EN signal is shown on trace 322, the D input is shown as trace 324 and the Q output is shown as trace 326. In this example, at the rising edge of the EN signal, the D input is provided through the flip-flop 302 causing the Q output to transition state from logic low to logic high. The flip-flop 302 may also be configured to transition state on the falling edge of the EN signal 322. As shown by the D trace 324, there is an additional delay “n” provided by the delay element 355a to the D input signal from the time the EN signal transitions to the time the D signal transitions.

FIG. 4A is a schematic diagram 400 illustrating an exemplary embodiment of a flip-flop having an integrated selectable hold delay. The flop-flop 402 comprises a data “D” input 406, an enable “EN” input 407, and a “Q” output 408. There may also be a “Q bar” output, which has the opposite polarity of the “Q” output. The “Q bar” output is not shown.

The flip-flop 402 also comprises a variable delay element 450. The variable delay element 450 is an alternative embodiment of the variable delay element 250 of FIG. 2A, and in this embodiment is schematically illustrated as having a delay element 455a and a delay element 455n. The variable delay element 450 may comprise more than two delay elements 455. In FIG. 4A, the D input on connection 406 is illustrated as being coupled to the delay element 455a and to the delay element 455n, and then to the Q output on connection 408 so that the D input signal on connection 406 experiences two delay periods, that is, the delay provided by both the delay element 455a and the delay element 455n. Although the embodiment shown in FIG. 4A applies two delay periods to the D input that is larger than a delay applied to the D input signal by the flip-flop 202 or the flip-flop 302, in FIGS. 2A and 3A, respectively, the variable delay element 450 and the flip-flop 402 has the same area, circuit layout and space requirements as the flip-flop 202 in FIG. 2A and the flip-flop 302 in FIG. 3A. Accordingly, the illustrative exemplary embodiment of the flip-flop 402 having the variable delay element 450 can comprise identical external connection as the flip-flop 202 having the variable delay element 250 and the flip-flop 302 having the variable delay element 350.

FIG. 4B is a basic timing diagram of the flip-flop of FIG. 4A. The EN signal is shown on trace 422, the D input is shown as trace 424 and the Q output is shown as trace 426. In this example, at the rising edge of the EN signal, the D input is provided through the flip-flop 402 causing the Q output to transition state from logic low to logic high. The flip-flop 402 may also be configured to transition state on the falling edge of the EN signal 422. As shown by the D trace 424, there is an additional delay “2n” provided by the delay element 455a and the delay element 455n to the D input signal from the time the EN signal transitions to the time the D signal transitions.

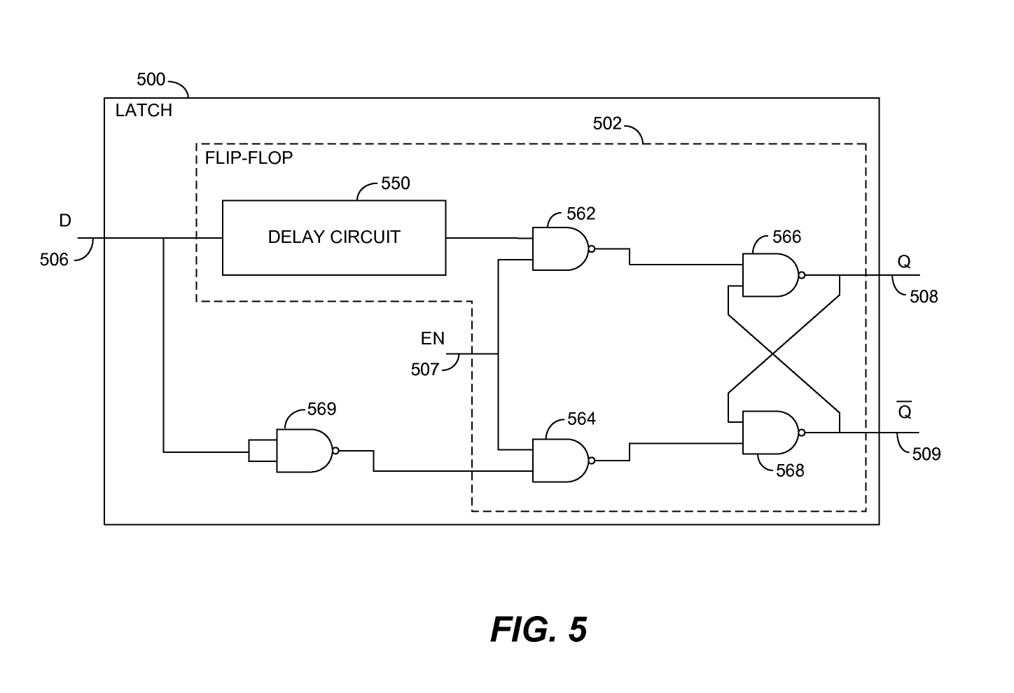

FIG. 5 is a schematic diagram illustrating a latch circuit 500 having an exemplary embodiment of a flip-flop having an integrated selectable hold delay. The latch circuit 500 comprises a flip-flop 502 having an integrated variable delay element 550. The flip-flop 502 comprises a data “D” input 506, an enable “EN” input 507, a “Q” output 508 and a “Q bar” output 509. The “Q bar” output 509 comprises the opposite polarity of the “Q” output 508 so that as the Q output transitions from logic low to logic high, the Q bar output transitions from logic high to logic low.

The flip-flop 502 is constructed using NAND gates 562, 564, 566 and 568. The NAND gate 569 operates as an inverter to reset the latch 500 to drive the Q output 508 to logic low if the D input 506 is logic high and the EN signal 507 is logic high.

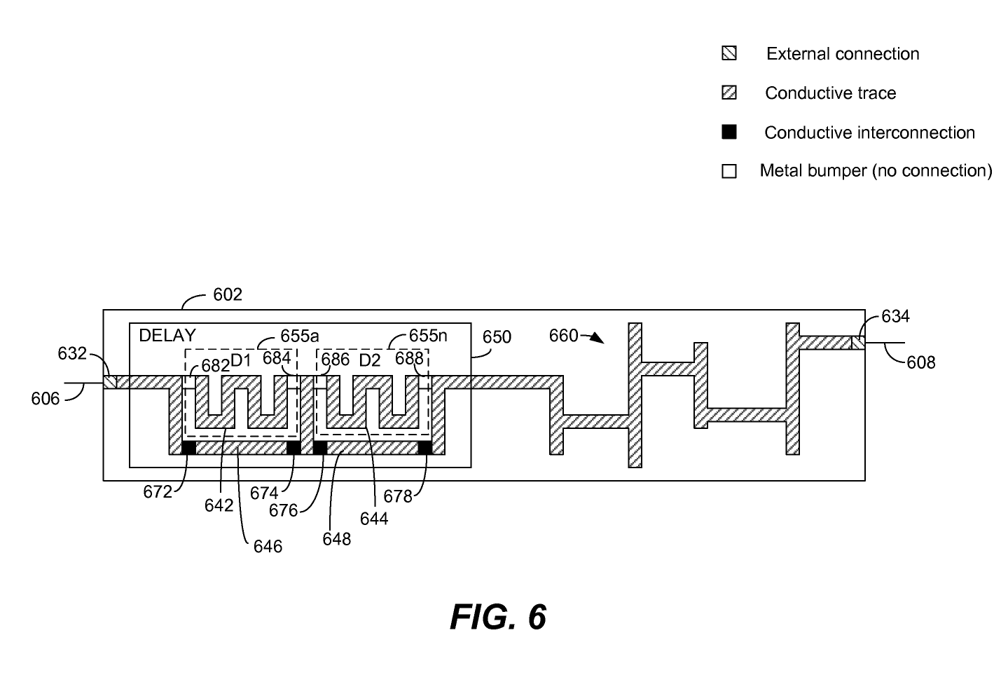

FIG. 6 is a diagram illustrating an embodiment of a layout of the flip-flop having an integrated selectable hold delay of FIG. 2A. The flip-flop 602 comprises a variable delay element 650 and circuitry 660. The circuitry 660 may comprise the logic elements that comprise the flip-flop 602 and are omitted for simplicity of illustration.

The flip-flop 602 comprises a D input 606, which is provided to an external connection 632 and a Q output 608 that is provided to an external connection 634. The external connection 632 and the external connection 634 are two illustrative examples of the external connections on the flip-flop 602 that couple the flip-flop 602 to the circuit in which it is being implemented. In this example, only two external connections are shown; however, external connections for the EN signal and the Q bar signal, along with other external connections, may also be provided.

In an exemplary embodiment, the variable delay element 650 comprises a delay element 655a (D1) and a delay element 655n (D2). The delay element 655a comprises electrically conductive traces 642, and metal bumper elements 682 and 684. The metal bumper elements 682 and 684 are electrically non-conductive and are sometimes referred to a metal blocking elements. The flip-flop 602 also comprises electrically conductive interconnections 672 and 674. The delay element 655n comprises electrically conductive traces 644, and metal bumper elements 686 and 688. The flip-flop 602 also comprises electrically conductive interconnections 676 and 678.

In the example shown in FIG. 6, the electrically conductive interconnections 672, 674, 676 and 678 are in place so that the D input signal from connection 606 is coupled to the electrically conductive traces 646 and 648 so that the D input signal bypasses the delay element 655a and the delay element 655n. The metal bumper elements 682, 684, 686 and 688 ensure that there is no electrical connection from the external connection 632 to the delay element 655a or the delay element 655n.

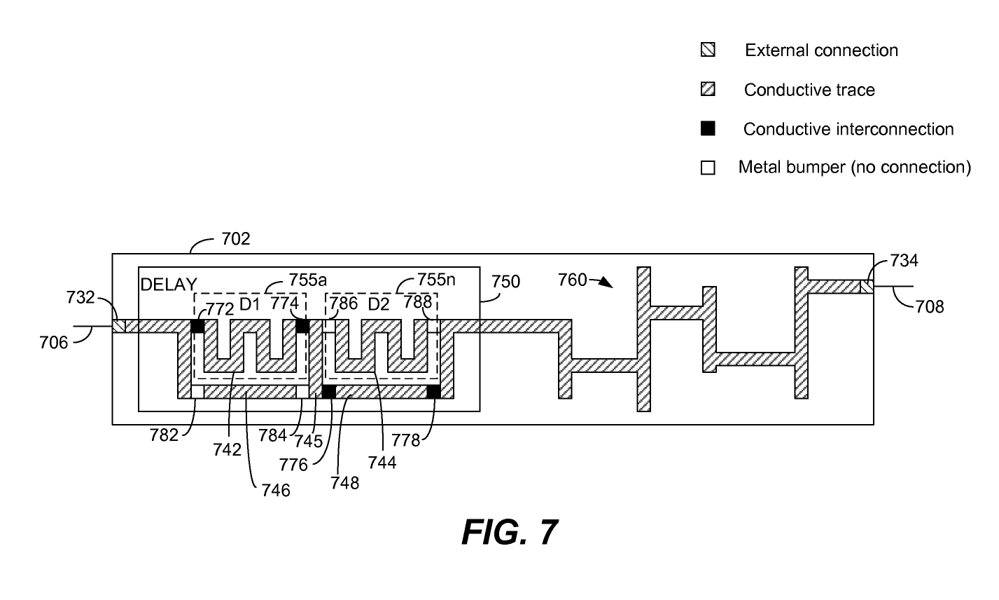

FIG. 7 is a diagram illustrating an embodiment of a layout of the flip-flop having an integrated selectable hold delay of FIG. 3A. The flip-flop 702 comprises a variable delay element 750 and circuitry 760. The circuitry 760 may comprise the logic elements that comprise the flip-flop 702 and are omitted for simplicity of illustration.

The flip-flop 702 comprises a D input 706, which is provided to an external connection 732 and a Q output 708 that is provided to an external connection 734. The external connection 732 and the external connection 734 are two illustrative examples of the external connections on the flip-flop 702 that couple the flip-flop 702 to the circuit in which it is being implemented. In this example, only two external connections are shown; however, external connections for the EN signal and the Q bar signal, along with other external connections, would be provided. The locations of the external connections 732 and 734 on the flip-flop 702 are in the same locations relative to the external connections 632 and 634 on the flip-flop 602 regardless of the delay period provided by the variable delay element 750.

In an exemplary embodiment, the variable delay element 750 comprises a delay element 755a (D1) and a delay element 755n (D2). The delay element 755a comprises electrically conductive traces 742 and electrically conductive interconnections 772 and 774.

The flip-flop 702 also comprises metal bumper elements 782 and 784, which are electrically non-conductive. The delay element 755n comprises electrically conductive traces 744 and metal bumper elements 786 and 788. The flip-flop 702 also comprises electrically conductive interconnections 776 and 778.

In the example shown in FIG. 7, the electrically conductive interconnections 772, 774, 776 and 778 are in place so that the D input signal from connection 706 travels through the delay element 755a and is then coupled to the electrically conductive traces 745 and 748 so that the D input signal bypasses only the delay element 755n. The metal bumper elements 786 and 788 ensure that there is no electrical connection from the delay element 755a to the delay element 755n.

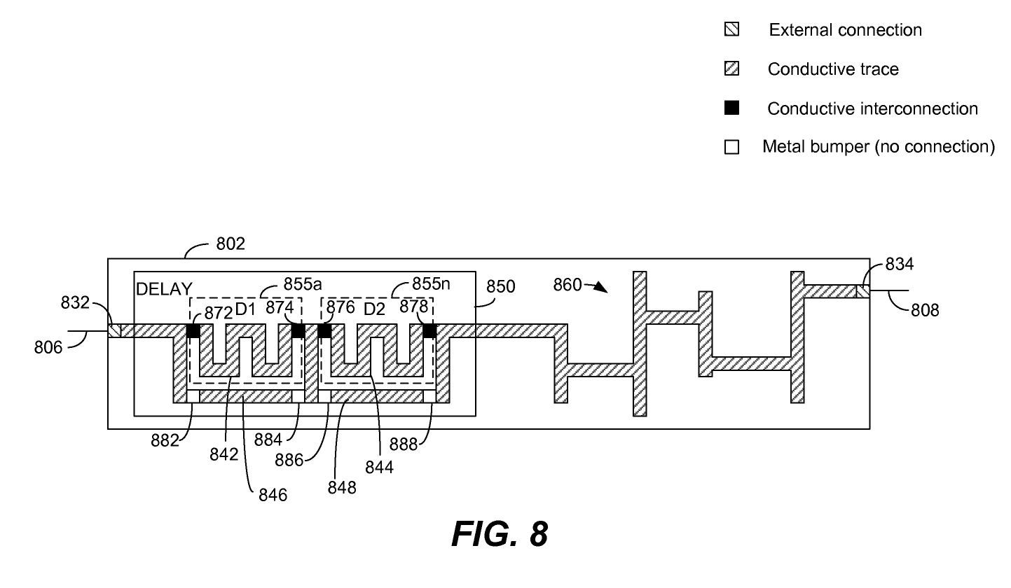

FIG. 8 is a diagram illustrating an embodiment of a layout of the flip-flop having an integrated selectable hold delay of FIG. 4A. The flip-flop 802 comprises a variable delay element 850 and circuitry 860. The circuitry 860 may comprise the logic elements that comprise the flip-flop 802 and are omitted for simplicity of illustration.

The flip-flop 802 comprises a D input 806, which is provided to an external connection 832 and a Q output 808 that is provided to an external connection 834. The external connection 832 and the external connection 834 are two illustrative examples of the external connections on the flip-flop 802 that couple the flip-flop 802 to the circuit in which it is being implemented. In this example, only two external connections are shown; however, external connections for the EN signal and the Q bar signal, along with other external connections, would be provided. The locations of the external connections 832 and 834 on the flip-flop 802 are in the same locations relative to the external connections 632 and 634 on the flip-flop 602, and in the same locations relative to the external connections 732 and 734 on the flip-flop 702 regardless of the delay period provided by the variable delay element 850.

In an exemplary embodiment, the variable delay element 850 comprises a delay element 855a (D1). The delay element 855a comprises electrically conductive traces 842 and electrically conductive interconnections 872 and 874. The flip-flop 802 also comprises metal bumper elements 882 and 884. The metal bumper elements 882 and 884 are electrically non-conductive. The delay element 855n comprises electrically conductive traces 844 and electrically conductive interconnections 876 and 878. The flip-flop 802 also comprises metal bumper elements 886 and 888, which are electrically non-conductive.

In the example shown in FIG. 8, the electrically conductive interconnections 872, 874, 876 and 878 are in place so that the D input signal from connection 806 travels through the delay element 855a and the delay element 855n. The metal bumper elements 882, 884, 886 and 888 ensure that there is no electrical connection from the external connection 832 to the conductive traces 846 and 848.

The variable delay elements 650, 750 and 850 are designed to provide a range of different delay values, while the artwork of each of the flip-flop cells have the same geometric dimensions, port locations and metal blockages so that they are footprint compatible with each other and easily interchanged. In actual design use, it allows an existing flip-flop having an integrated selectable hold delay to be exchanged with another flip-flop having a different delay by exchanging the flip-flop in a circuit without having to rework the existing circuit placement and route connections, and without causing design-rule violations.

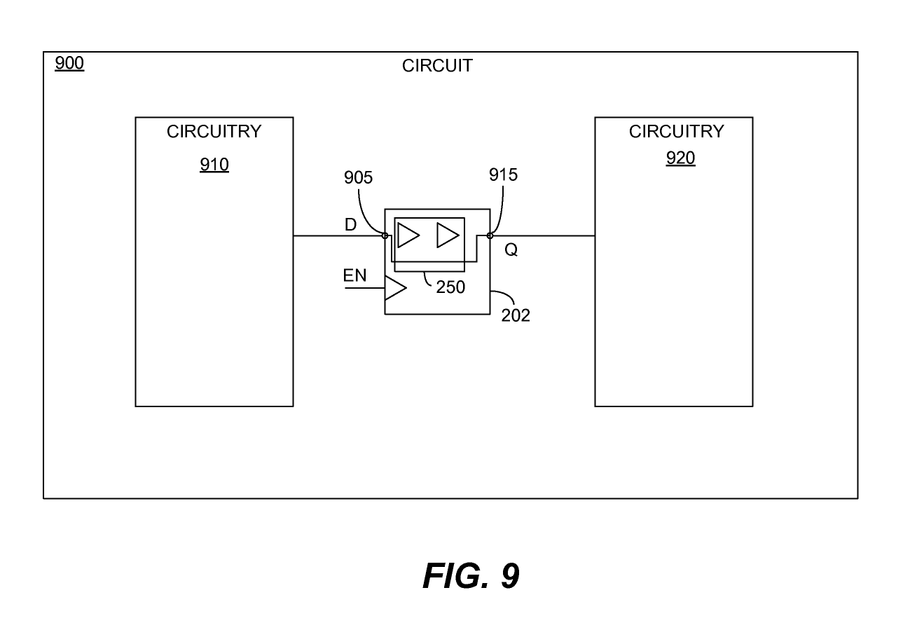

FIG. 9 is a block diagram showing the flip-flop having an integrated selectable hold delay of FIG. 2A placed in an integrated circuit. In an exemplary embodiment, the integrated circuit 900 comprises circuitry 910 and circuitry 920. The circuitry 910 and the circuitry 920 can be any circuitry located within the integrated circuit 900. In an exemplary embodiment, the flip-flop 202 of FIG. 2A is placed in the integrated circuit 900 between the circuitry 910 and the circuitry 920. The circuitry 910 is coupled to the flip-flop 202 at a node, or point 905 and the circuitry 920 is coupled to the flip-flop 202 at a node, or point 915. The flip-flop 202 has a variable delay element 250 having a first selectable delay.

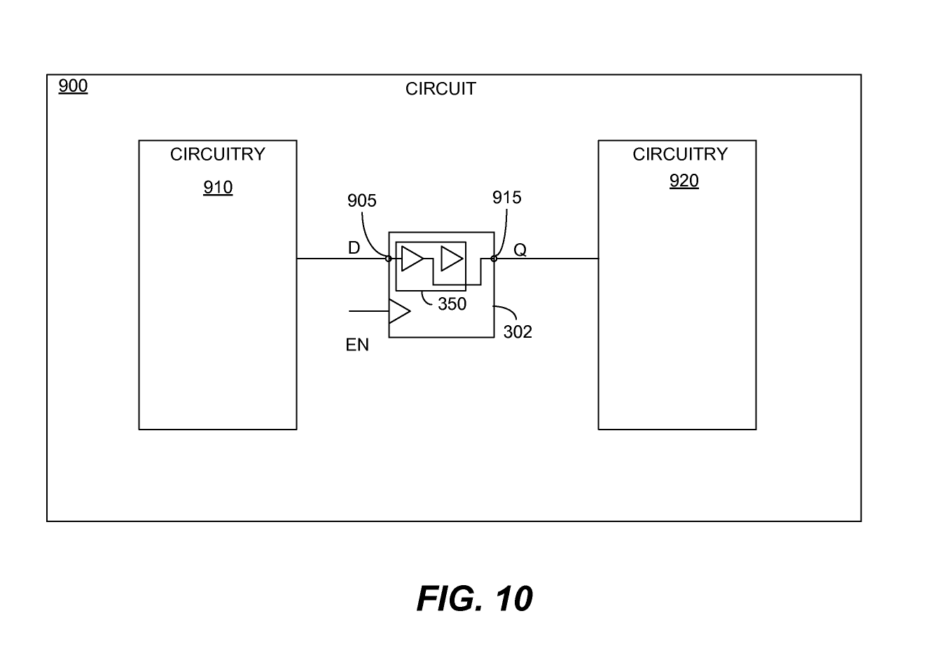

FIG. 10 is a block diagram showing the flip-flop having an integrated selectable hold delay of FIG. 3A placed in the integrated circuit of FIG. 9. The flip-flop 302 has a variable delay element 350, which has a second selectable delay that is different than the first selectable delay of the variable delay element 250 in FIG. 9. In accordance with an exemplary embodiment, the circuitry 910 is coupled to the flip-flop 302 at the node, or point 905 and the circuitry 920 is coupled to the flip-flop 302 at a node, or point 915. In this manner flip-flops having different selectable delays can be incorporated into an integrated circuit 900 using identical connection points, which, in this example, are the nodes 905 and 915.

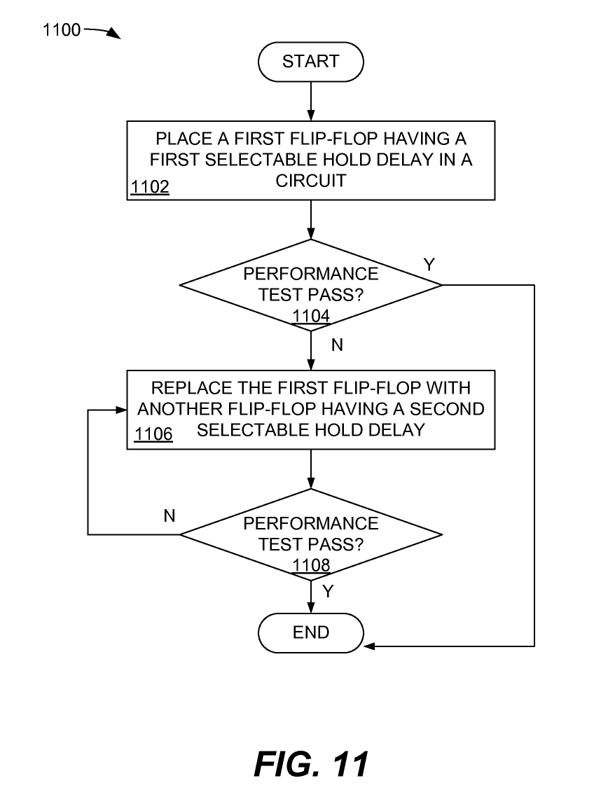

FIG. 11 is a flow chart describing an exemplary method for using a flip-flop having an integrated selectable hold delay.

In block 1102, a first flip-flop having a first selectable hold delay is placed in a circuit.

In block 1104, a performance test is performed on the circuit to determine timing. If the circuit passes the performance test, the process ends.

If the circuit does not pass the performance test, then in block 1106, the first flip-flop having the first selectable hold delay is replaced with another flip-flop having a second selectable hold delay.

In block 1108, the performance test is performed on the circuit to determine timing. If the circuit passes the performance test, the process ends. If the circuit still does not pass the performance test, the process returns to block 1106 where the second flip-flop having the second selectable delay is replaced with another flip-flop having another selectable delay. The process repeats until the performance test is passed.

This disclosure describes the invention in detail using illustrative embodiments. However, it is to be understood that the invention defined by the appended claims is not limited to the precise embodiments described.

What is claimed is:

1. A circuit, comprising:
a flip-flop; and
a delay circuit integrated with the flip-flop, the delay circuit comprising at least one delay element, the flip-flop and delay circuit having a predefined architecture such that a delay provided by the delay circuit may have a selectable delay value while the flip-flop remains within the predefined architecture.

2. The circuit of claim 1, wherein the predefined architecture comprises predefined geometric relationships, port locations and metal blocking areas regardless of the delay provided by the delay circuit.

3. The circuit of claim 2, wherein multiple instances of the flip-flop and integrated delay circuit having different delays can be interchanged in an integrated circuit without introducing design-rule violations.

4. The circuit of claim 3, wherein the delay circuit comprises a plurality of delay elements.

5. The circuit of claim 4, wherein the selectable delay value is chosen based on a desired timing delay of a signal propagating through the flip-flop.

6. The circuit of claim 5, wherein the selectable delay value is configured to range from zero delay to a maximum delay defined by the at least one delay element.

7. The circuit of claim 6, further comprising a bypass circuit configured to provide the zero delay.

8. The circuit of claim 6, wherein a plurality of delay elements are configured to establish a selectable delay value between the zero delay and the maximum delay.

9. The device of claim 6, wherein the delay establishes a hold delay for a D input of the flip-flop.

10. A method, comprising:
placing a first flip-flop having a first delay in an integrated circuit;
performance testing the integrated circuit; and
if the performance testing indicates, replacing the first flip-flop with a second flip-flop having a second delay.

11. The method of claim 10, wherein the first flip-flop and the second flip-flop have a predefined architecture comprising predefined geometric relationships, port locations and metal blocking areas regardless of the first delay and the second delay.

12. The method of claim 11, wherein the first flop-flop and the second flip-flop can be interchanged in the integrated circuit without introducing design-rule violations.

13. The method of claim 12, wherein the delay is selectable.

14. The method of claim 13, further comprising selecting the delay based on a desired timing delay of a signal propagating through the first flip-flop.

15. The method of claim 14, wherein the selectable delay is configured to range from zero delay to a maximum delay.

16. The method of claim 15, wherein a bypass circuit provides the zero delay.

17. The method of claim 15, wherein a plurality of delay elements are configured to establish a selectable delay between the zero delay and the maximum delay.

18. The method of claim 15, wherein the delay establishes a hold delay for a D input of the flip-flop.

19. A circuit, comprising:
a flip-flop; and
a delay circuit integrated with the flip-flop, the delay circuit comprising at least one delay element, the flip-flop and delay circuit having a predefined architecture such that a delay provided by the delay circuit may have a selectable delay value while the flip-flop remains within the predefined architecture, wherein multiple instances of the flip-flop and integrated delay circuit having different delays can be interchanged in an integrated circuit without introducing design-rule violations.

20. The circuit of claim 19, wherein the selectable delay value is chosen based on a desired timing delay of a signal propagating through the flip-flop.
